(19) United States
(12) Patent Application Publication
(10) Pub. No.: US 2025/0087613 A1
(43) Pub. Date: Mar. 13, 2025

(54) SEMICONDUCTOR CHIP, METHOD FOR PRODUCING A SEMICONDUCTOR CHIP AND ARRANGEMENT

(71) Applicant: ams-OSRAM International GmbH, Regensburg (DE)

(72) Inventors: Fabian KOPP, Tanjung Tokong (MY); Attila MOLNAR, Gelugor (MY); Ban Loong Chris NG, Paya Terubong (MY); Hein Yoong LEOW, Bayan Lepas (MY)

(21) Appl. No.: 18/723,879

(22) PCT Filed: Dec. 27, 2021
(86) PCT No.: PCT/EP2021/087679

§ 371 Date: Jun. 25, 2024

(51) Int. Cl. H01L 23/00

(52) U.S. Cl. CPC H01L 24/13; H01L 24/11; H01L 24/16; H01L 2224/1145; H01L 2224/115; H01L 2224/13011; H01L 2224/13018; H01L 2224/13082; H01L 2224/13083; H01L 2224/13166; H01L 2224/16227

(57) ABSTRACT

A semiconductor chip includes an epitaxial semiconductor layer sequence, a solder layer arranged over a back side face of the epitaxial semiconductor layer sequence, a buffer layer arranged between the back side face of the epitaxial semiconductor layer sequence and the solder layer. The buffer layer includes a porous and/or rough metal.

### RELATED APPLICATIONS

This application is a US National Stage Application of International Application PCT/EP2021/087679, filed on 27 Dec. 2021.

### FIELD

The present disclosure relates to semiconductor chips, a method for producing semiconductor chips and an arrangement.

### SUMMARY

The present disclosure relates to a semiconductor chip, which can be connected to a connection carrier in an improved and particularly mechanically stable manner. Further aspects relate to an improved method for producing a semiconductor chip and an improved arrangement with a semiconductor chip being connected to a connection carrier in a mechanically stable manner are to be provided.

According to an embodiment of a present disclosure, a semiconductor chip comprises an epitaxial semiconductor layer sequence. For example, the semiconductor chip is an optoelectronic semiconductor chip configured to emit and/or detect electromagnetic radiation during operation. For example, the epitaxial semiconductor layer sequence is based on a III-V semiconductor compound material, for example a III-nitride compound material, a III-phosphide compound material or a III-arsenide compound material.

Further, the epitaxial semiconductor layer sequence has a growth direction, in which the epitaxial semiconductor layers of the epitaxial semiconductor layer sequence are epitaxially grown above each other.

According to a further embodiment of the semiconductor chip, a solder layer is arranged over a back side face of the epitaxial semiconductor layer sequence. With the term “over” it is particularly indicated that the elements concerned are not necessarily in direct physical contact with each other. Rather, further elements might be arranged between them. The back side face of the epitaxial semiconductor layer sequence is particularly arranged perpendicular to the growth direction. In particular, the solder layer comprises or consists of a solderable material.

According to a further embodiment of the semiconductor chip a buffer layer is arranged between the back side face of the epitaxial semiconductor layer sequence and the solder layer. In an example, the buffer layer comprises a porous and/or rough metal or consists of a porous and/or rough metal. Particularly, with the term “porous” it is meant that a volume region of the buffer layer is embodied in a porous manner. For example, the buffer layer comprises pores, voids or recesses, which are filled with a gas such as air. With the term “rough” it is particularly meant that the buffer layer has a rough surface, in particular with peaks.

In particular, the semiconductor chip includes:
an epitaxial semiconductor layer sequence,
a solder layer arranged over a back side face of the epitaxial semiconductor layer sequence,
a buffer layer arranged between the back side face of the epitaxial semiconductor layer sequence and the solder layer, wherein
the buffer layer comprises a porous and/or rough metal.

Aspects of the present disclosure can provide a porous and/or rough buffer layer between the solder layer and the semiconductor chip. In particular, due to the porosity of the buffer layer, the buffer layer can absorb mechanical stress, which is generated for example by thermal impact or mechanical impact, particularly, if the semiconductor chip is connected to a further element such as a connection carrier by soldering. Consequently, reliability of an arrangement comprising the semiconductor chip being connected via a solder joint to a separate element can be improved.

According to a further embodiment of the semiconductor chip, the porous metal comprises porous titanium or is porous titanium. In an example, the buffer layer has a thickness between 500 nanometers and 3000 nanometers, both inclusive.

According to a further embodiment of the semiconductor chip, at least one electrical contact is arranged over the back side face of the epitaxial semiconductor layer sequence. Particularly, the electrical contact is configured to provide the epitaxial semiconductor layer sequence and in particular the active layer with a current during operation. Further, the semiconductor chip comprises a second electrical contact, which can also be arranged over the back side face of the epitaxial semiconductor layer sequence or over a front side face of the epitaxial semiconductor layer sequence, the front side face being arranged opposite to the back side face. In particular, the buffer layer is arranged between the electrical contact and the solder layer.

For example, the solder layer comprises or consists of at least one of the following materials: nickel, platinum, tin, gold. For example, the solder layer has a thickness between 150 nanometers and 40000 nanometers, both inclusive.

For example, the solder layer consists of a nickel layer. The nickel layer has, for example, a thickness between 300 nanometers and 600 nanometers, both inclusive. In an example, the nickel layer has a thickness of about 400 nanometers.

For example, the solder layer comprises a nickel layer and a platinum layer or consists of a nickel layer and a platinum layer. In this case, the nickel layer has, for example, a thickness between 300 nanometers and 500 nanometers, both inclusive, whereas the platinum layer has, for example, a thickness between 100 nanometers and 300 nanometers, both inclusive. In an example, the nickel layer has a thickness of about 350 nanometers and the platinum layer has a thickness of about 100 nanometers.

For example, the solder layer consists of a platinum layer. In this case, the platinum layer has, for example, a thickness between 150 nanometers and 300 nanometers, both inclusive. In an example, the platinum layer has a thickness of about 200 nanometers.

Further, the solder layer comprises or consists of a gold/tin alloy, for example. In this case, the thickness of the solder layer is, for example, between 1500 nanometers and 4500 nanometers, both inclusive. In an example, the gold/tin layer has a thickness of about 3500 nanometers.

According to a further embodiment of the semiconductor chip the solder layer is a tin layer. The tin layer has, for example, a thickness between 5000 nanometers and 40000 nanometers, both inclusive. In an example, the tin layer has a thickness of about 10000 nm.

According to a further embodiment of the semiconductor chip, a cross-sectional area of the buffer layer decreases in a direction from the back side face of the epitaxial semiconductor layer sequence to the solder layer. In an example, the decrease of the cross-sectional area of the buffer layer is continuous. In other words, side faces of the buffer layer are free of kinks. In this embodiment of the semiconductor chip the buffer layer is tapered.

According to a further embodiment of the semiconductor chip a side face of the buffer layer encloses an acute angle with the back side face of the epitaxial semiconductor layer sequence. For example, the acute angle has a value between 15° and 60°, both inclusive.

According to a further embodiment of the semiconductor chip, the buffer layer has a rough surface with peaks and the solder layer is formed of islands on or over the peaks. With the term “on” it is meant that the solder layer is in direct contact with the peaks of the rough surface. Particularly, the islands are not directly connected to each other. In other words, the solder layer is formed in a non-continuous manner of islands that are separated from each other. The island can be an direct contact with the buffer layer or arranged over the buffer layer. If the buffer layer has a rough surface with peaks and islands of the solder layer separated from each other are formed on or over the peaks of the rough surface, the buffer function, particularly the property to absorb mechanical stress, is improved.

According to a further embodiment of the semiconductor chip, a cap layer is arranged over the solder layer. For example, the cap layer is in direct contact with the solder layer. As the solder layer, also the cap layer can be solderable. In particular, the cap layer comprises or consists of a metal. In particular, the cap layer comprises or consists of one of the materials of the solder layer. For example, the cap layer comprises or consists of gold. Particularly, the cap layer is freely accessible from the outside. For example, the cap layer has a thickness between 50 nanometers and 250 nanometers, both inclusive. In an example, the cap layer has a thickness of about 100 nanometers.

According to a further embodiment of the semiconductor chip, the buffer layer has a rough surface having peaks and the cap layer formed of islands is arranged over the peaks. Also, the islands of the cap layer can be separated and not connected to each other.

According to a further embodiment of the semiconductor chip the buffer layer has a porosity with a gradient. For example, the porosity of the buffer layer increases from the back side face of the semiconductor chip to the solder layer or vice versa. With the gradient in porosity, the buffer function can be adapted in a specified manner.

According to a further embodiment of the semiconductor chip, the buffer layer has at least two sublayers comprising or consisting of the same porous metal, but having different porosities. It is also possible that the buffer layer has more than two sublayers of the same material, but different porosity.

According to a further embodiment of the semiconductor chip, the buffer layer comprises a plurality of porous sublayers and a plurality of dense sublayers, the porous sublayers and the dense sublayers having different materials and being arranged alternatingly. In particular, the dense sublayers have a very low or no porosity compared to the porous sublayers. For example, the dense sublayer comprise or consist of one of the following materials: platinum, rhodium.

According to a further embodiment of the semiconductor chip, at least one of the following layers is arranged between the buffer layer and the back side of the epitaxial semiconductor layer sequence: an adhesion layer, a reflection layer.

The adhesion layer can enhance an adhesion to the back side face of the epitaxial semiconductor layer sequence and particularly to an electrical contact which might be arranged at the back side face of the epitaxial semiconductor layer sequence. For example, the adhesion layer is in direct contact with the electrical contact. The adhesion layer might comprise or might consist of at least one of the following materials: titanium, chromium, aluminum. For example, the adhesion layer has a thickness between 0.1 nanometers and 200 nanometers, both inclusive. In an example, the adhesion layer has a thickness of about 5 nanometers.

The reflection layer might be part of the semiconductor chip, if the semiconductor chip has an active layer configured to generate and/or detect electromagnetic radiation, for example, visible light, during operation. In this case, the reflection layer is configured in particular to reflect electromagnetic radiation generated and/or detected by the active layer.

For example, the reflection layer comprises or consists of one of the following materials: aluminum, copper, rhodium. For example, the reflection layer is an aluminum layer and has a thickness between 50 nanometers and 700 nanometers, both inclusive. In an example, the aluminum layer has a thickness between 300 nanometers and 500 nanometers, both inclusive. For example, the reflection layer comprises or consists of an aluminum/copper alloy, wherein the copper portion is about 2%. The aluminum/copper layer has, for example, a thickness between 50 nanometers and 700 nanometers, both inclusive. In an example, the aluminium/copper alloy layer has a thickness between 300 nanometers and 500 nanometers, both inclusive. For example, the reflection layer is a rhodium layer with a thickness between 50 nanometers and 500 nanometers, both inclusive. In an example, the rhodium layer has a thickness of about 70 nanometers.

For example, the semiconductor chip is produced with the method described in the following. Features, developments and embodiments, which are disclosed in connection with the semiconductor chip are also disclosed for the method and vice versa.

According to an embodiment of the method for producing a semiconductor chip, an epitaxial semiconductor layer sequence with a back side face is provided. For example, the epitaxial semiconductor layer sequence is epitaxially grown on a growth substrate having the same or a similar lattice constant as the epitaxial semiconductor layer sequence.

According to a further embodiment of the method, a buffer layer is arranged over the back side face.

According to a further embodiment of the method, a solder layer is arranged over the buffer layer.

According to a further embodiment of the method, the buffer layer comprises a porous and/or rough metal or consists of a porous and/or rough metal.

According to an embodiment, the method comprises the following steps:
providing an epitaxial semiconductor layer sequence with a back side face,
arranging a buffer layer over the back side face, and
arranging a solder layer over the buffer layer, wherein
the buffer layer comprises a porous and/or rough metal.

Particularly, the steps of the method given above are conducted in the given order.

According to a further embodiment of the method, the step of arranging the buffer layer comprises the deposition of a metal by e-beam evaporation under an ion flow. In other words, the buffer layer is, for example, deposited by e-beam evaporation under an ion-flow. Particularly, the ion-flow comprises or consists of ions of a noble gas, for example of argon. In particular, the porosity and/or the roughness of the buffer layer increases with increasing ion-flow. If a dense sublayer of the buffer layer is to be achieved, no ion-flow is used during the deposition, in particular.

According to a further embodiment of the method, the step of arranging the buffer layer comprises the deposition of a metal by e-beam evaporation under an oblique angle or by sputtering under an oblique angle. In particular, a material flow of the metal to be deposited includes an oblique angel with the back side face of the epitaxial semiconductor layer sequence. For example, the oblique angel has a value between 10° and 70°, inclusive. E-beam evaporation of a metal under an oblique angle is for example disclosed in M. Wu et al., J. of Appl. Phys., 124, 055301 (2018) (DOI: 10.1063/1.5044570), which is incorporated herein by reference. Sputtering of a metal under an oblique angle is for example disclosed in R. Alvarez et al., JPhysD-106465.R1 (DOI: 10.1088/0022-3727/49/4/045303), which is also incorporated herein by reference.

According to a further embodiment of the method, the step of arranging the buffer layer comprises wet chemical etching. For example, a porous and/or rough metal layer is at first deposited by e-beam evaporation under an ion flow over the back side face of the epitaxial semiconductor layer sequence and is wet chemically etched in a subsequent step in order to form the buffer layer. In particular, the porosity and/or the roughness of the buffer layer is enhanced by the wet chemical etching. Further, the porosity and/or the roughness of the buffer layer is enhanced with etching time. For example, a porous and/or rough buffer layer, which comprises porous and/or rough titanium, is wet chemical etched with an etchant comprising hydrofluoric acid and hydrogen peroxide.

For example, the semiconductor chip disclosed above is comprised by arrangement with a further element such as a connection carrier. All features, developments and embodiments, which are disclosed in connection with the semiconductor chip are also disclosed for the arrangement and vice versa.

According to an embodiment, the arrangement comprises a semiconductor chip. For example the semiconductor chip is embodied as already described.

According to a further embodiment, the arrangement comprises a connection carrier with a mounting area. For example, the connection carrier is a printed circuit board (PCB). The mounting area is part of a main surface of the connection carrier and configured such that the semiconductor chip can be mounted on the mounting area. For example, the mounting area is configured such that the semiconductor chip can be soldered to the mounting area.

According to a further embodiment of the arrangement, the semiconductor chip is at least mechanically stably connected to the mounting area of the connection carrier by a solder joint. The solder joint is, for example, generated during a solder process and comprises or consists of the material of the solder layer and/or a solder paste being deposited on the connection carrier before soldering. Further, the solder joint comprises all or some of the material of the cap layer, for example.

According to a further embodiment of the arrangement, the buffer layer is arranged between the solder joint and the mounting area. In an example, the buffer layer is in direct contact with the solder joint.

According to a further embodiment of the arrangement, the semiconductor chip is also electrically conductively connected to the mounting area of the connection carrier by the solder joint. In this embodiment of the arrangement, a back side face of the semiconductor chip is embodied in an electrically conductive manner and the semiconductor chip is configured to be electrically connected via its back side face. Further, in this embodiment the buffer layer is electrically conductive.

According to a further embodiment of the arrangement, the semiconductor chip is a flip-chip. A flip-chip particularly comprises two electrical contacts arranged over the back side face of the epitaxial semiconductor layer sequence and being configured to mechanically stably and electrically conductively connect the semiconductor chip to a further element such as the connection carrier.

According to a further embodiment of the arrangement, the semiconductor chip is a thin-film chip. In particular, the thin-film chip is free of a growth substrate of the epitaxial semiconductor layer sequence. Instead, the thin-film chip, comprises, for example, a further carrier being different from the growth substrate for mechanical stability. For example, the thin-film chip comprises two electrical contacts over a front side of the epitaxial semiconductor layer sequence. In that case, the buffer layer must not be electrically conductive.

### BRIEF DESCRIPTION OF THE DRAWINGS

Embodiments of the present disclosure including embodiments and developments of the semiconductor chip, the method for producing a semiconductor chip and the arrangement can be described by way of example in connection with the following drawings:

FIGS. 1 to 4 show schematic stages of a method for producing a semiconductor chip according to an exemplary embodiment.

FIG. 5 shows images of a layer stack according to an aspect of the present disclosure.

FIG. 6 shows measured values of the roughness of the layer stack shown in FIG. 5.

FIG. 7 shows measured values of residual stress of a titanium layer according to an aspect of the present disclosure.

FIG. 8 shows an image of a rough and porous titanium buffer layer according to an aspect of the present disclosure.

FIG. 9 shows a cut out from FIG. 8 with a volume region of the titanium layer.

FIG. 9 shows a cut out from FIG. 8 with a volume region of the titanium layer.

FIG. 10 shows a titanium layer being deposited with e-beam evaporation under an argon flow 7 and being subsequently wet chemically etched according to an aspect of the present disclosure.

FIGS. 11 to 19 show schematic views of semiconductor chips according to several exemplary embodiments of the present disclosure.

FIG. 20 shows a raster electron microscope image of a cross section of a semiconductor chip according to an aspect of the present disclosure.

FIG. 21 shows a schematic sectional view of an arrangement before the connection of the semiconductor chip to a connection carrier according to an aspect of the present disclosure.

FIGS. 22 to 24 show schematic sectional views of arrangements according to several embodiments of the present disclosure.

Equal or similar elements as well as elements of equal function are designated with the same reference signs in the drawings. The drawings and the proportions of the elements shown in the drawings are not regarded as being shown to scale. Rather, single elements, in particular layers, can be shown exaggerated in magnitude for the sake of better presentation and/or better understanding.

### DETAILED DESCRIPTION

During the method according to the exemplary embodiment of FIGS. 1 to 4, an epitaxial semiconductor layer sequence 1 is provided in a first step. The epitaxial semiconductor layer sequence 1 has an active layer 2 configured for generating electromagnetic radiation during operation. Further, the epitaxial semiconductor layer sequence 1 has a back side face 3 and a front side face 4 arranged opposite the back side face (FIG. 1).

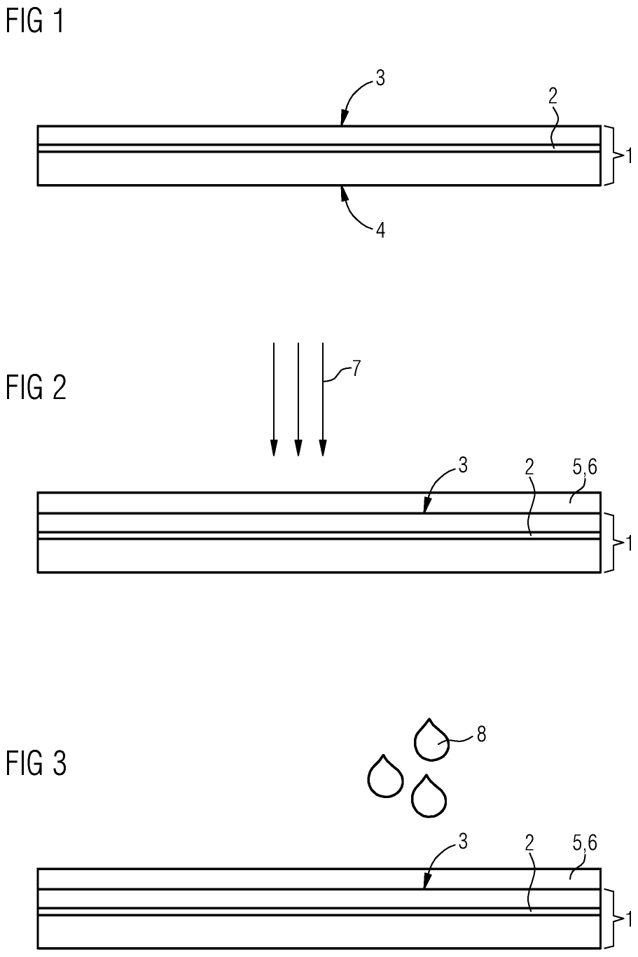

In order to arrange a porous and/or rough buffer layer 5 over the back side face 3 of the epitaxial semiconductor layer sequence 1, a titanium layer 6 is deposited over the back side face 3 of the epitaxial semiconductor layer sequence 1, in particular with e-beam evaporation under an argon flow 7 (FIG. 2). The titanium layer 6 deposited under argon flow 7 forms the porous and rough buffer layer 5 (see also FIGS. 5 to 7 with description). In particular, a volume region of the buffer layer 5 is porous while a surface of the buffer layer 5 is rough.

In a next step, the buffer layer 5 is wet chemically etched, for example with an etchant 8 comprising hydrofluoric acid HF, hydrogen peroxide H₂O₂ and deionized water (DI water) in a concentration of about 1:1:20 of HF: H₂O₂: DI water (FIG. 3).

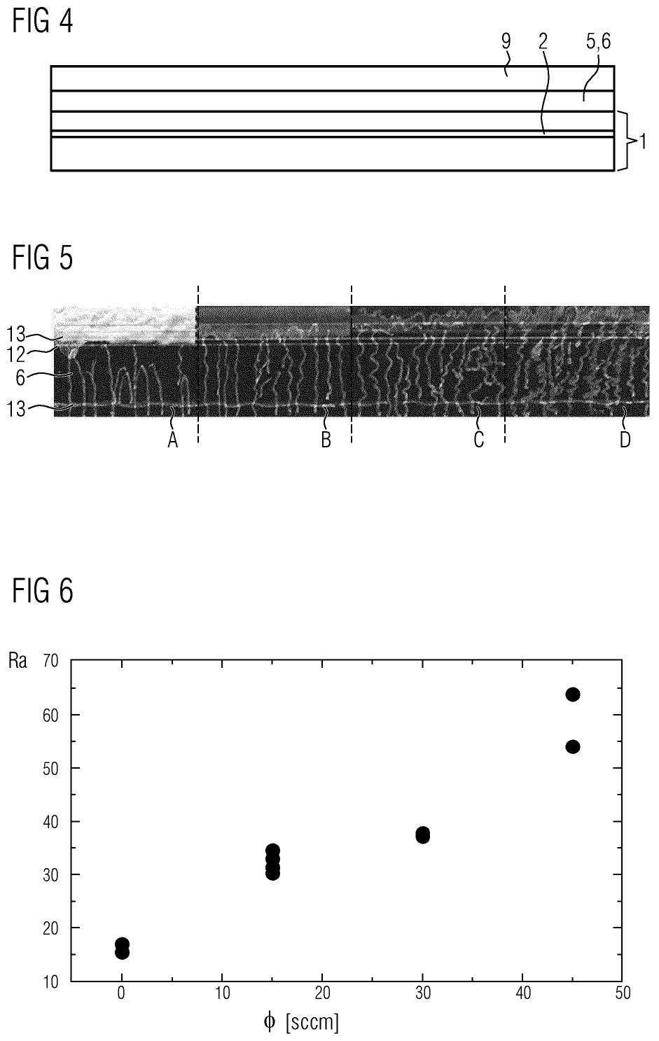

In a next step, a solder layer 9 is deposited over the buffer layer 5 (FIG. 4).

FIG. 5 shows four images of a focused ion beam microscope A, B, C, D, of a layer stack comprising the following layers in the given order:
a rhodium layer 10 with a thickness of about 70 nanometers,
a titanium layer 6 with a thickness of about 1150 nanometers,
a platinum layer 12 with a thickness of about 200 nanometers,
a gold layer 13 with a thickness of about 75 nanometers.

These layers are deposited on a silicon substrate (not shown) covered with a chromium layer (not shown) having a thickness of about 4 nanometers. For better illustration, the structure of the depicted layer stacks is enhanced by hand-drawings.

The titanium layer 6 of the layers stacks shown in images A to D are deposited by e-beam evaporation under an argon-flow 7, wherein the argon flow is increased from A to D.

The image marked with A shows a titanium layer 6 being deposited without any argon flow 7. As can be seen in image A, the titanium layer 6 is substantially dense without porosity of the volume and roughness of the surface.

The image marked with B of FIG. 5 shows a titanium layer 6 deposited under an argon flow 7 of 15 sccm. As can be seen in image B, the volume of the titanium layer 6 is porous and the surface of the titanium layer 6 is rough.

The image marked with C shows a titanium layer 6 deposited via e-beam deposition under an argon flow 7 with 30 sccm. It can be seen that the porosity of the volume of the titanium layer 6 as well as the roughness of the surface of the titanium layer 6 are enhanced compared to the titanium layer 6 of image B.

The titanium layer 6 shown in the image marked with D is deposited via e-beam evaporation under a further enhanced argon flow 7 of 45 sccm. The porosity of the volume region of the titanium layer 6, as well as the roughness of the surface titanium layer 6, are further enhanced.

The thickness of the layers of the layer stacks of FIG. 5 is controlled during deposition by measurement of the weight. Therefore, with increasing porosity, the thickness of the titanium layer 6 enhances from image A to image D as indicated by the horizontal lines in FIG. 5. Therefore, it can be concluded not only from the structure of the titanium layer 6 depicted in FIG. 5 but also from the height of the titanium layer 6 that the porosity of the titanium layer 6 is enhanced with enhanced argon flow 7.

FIG. 6 shows measured values of the roughness Ra of the layer stack shown in FIG. 5 at different values Φ of the argon flow 7 during deposition of the titanium layer 6 by e-beam evaporation. Ra is given by the deviations of a profile of the surface in the direction of a normal from a center line. As can be seen from FIG. 6, the roughness Ra of the surface of the layer stack, which is a measure of the roughness of the titanium layer 6 increases with argon flow during deposition.

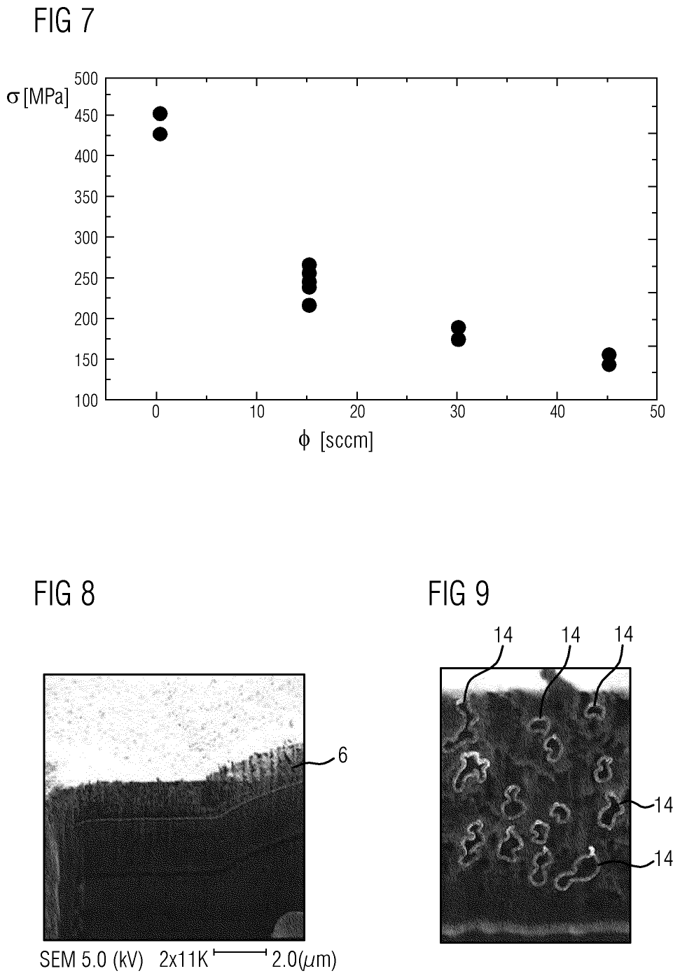

FIG. 7 shows measured values of the residual stress σ of the titanium layer 6 with increasing argon flow 7 during titanium evaporation via e-beam. As can be seen from FIG. 7, the residual stress σ decreases with argon flow 7 during titanium evaporation and therefore with increasing porosity and roughness of the titanium layer 6.

FIG. 8 shows a raster electron microscope image of a rough and porous titanium buffer layer 6 being wet chemically etched after deposition of the titanium with e-beam evaporation under an argon flow 7. FIG. 9 shows a cut out from FIG. 8 with a volume region of the titanium layer 6. As can be seen, the buffer layer 6 formed of porous and rough titanium comprises pores 14. For better illustration, the pores 14 are enhanced by hand-drawings.

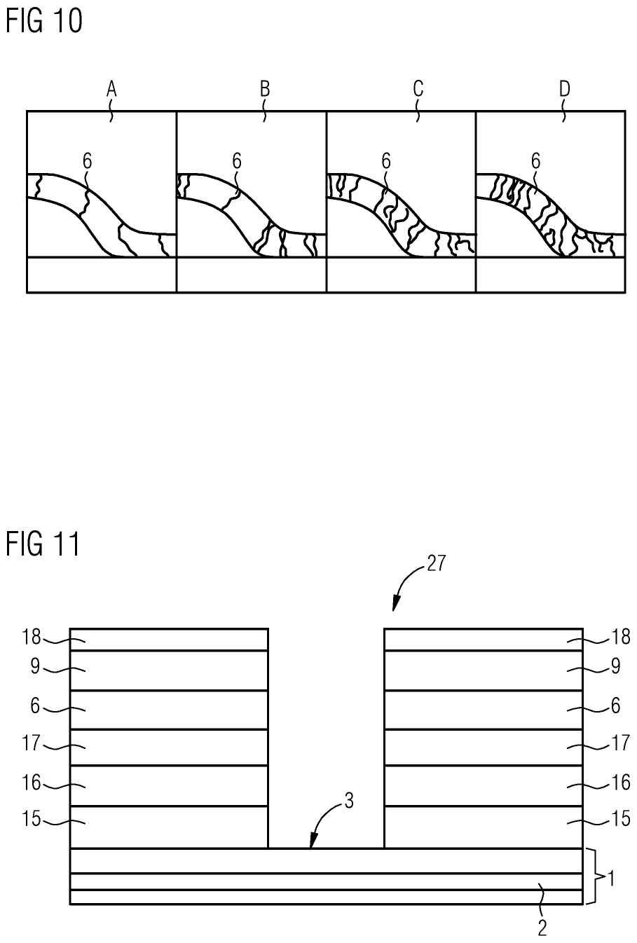

FIG. 10 comprises sections A to D each showing schematically a titanium layer 6 being deposited with e-beam evaporation under an argon flow 7 and being subsequently wet chemically etched. The etching time increases from section A to section D. The titanium layer 6 shown in section A was not wet chemically etched, while the titanium layer 6 of section B was etched for 2.5 minutes. The titanium layer 6 of section C was wet chemically etched for 4.5 minutes, while the titanium layer 6 shown in section D was etched for 6.5 minutes. As can be seen from FIG. 10, the porosity of the titanium layer 6 increases with etching time.

The semiconductor chip 27 according to the exemplary embodiment of FIG. 11 comprises an epitaxial semiconductor layer sequence 1 with an active layer 2. The active layer 2 is configured to generate electromagnetic radiation during operation. Two electrical contacts 15 are arranged on a back side face 3 of the epitaxial semiconductor layer sequence 1. An adhesion layer 16 is arranged in direct contact on the electrical contacts 15. A reflection layer 17 is arranged on the adhesion layer 16, also in direct contact. The adhesion layer 16 enhances the adhesion of the reflection layer 17 to the electrical contact 15. The reflection layer 17 is configured to reflect electromagnetic radiation generated within the active layer 2 during operation and redirect it to a front side face of the semiconductor chip 27 being part of a radiation emitting surface. A buffer layer 6 is arranged on the reflection layer 17 and a solder layer 9 is arranged on the buffer layer 6. The solder layer 9 is covered with a cap layer 18.

The adhesion layer 16, the reflection layer 17, the solder layer 9 and the cap layer 18 can comprise or consist of the materials already disclosed in the general part of the description. Also thicknesses of these layers are given therein.

The buffer layer 6 of the exemplary embodiment of FIG. 11 is, in particular, formed from porous and rough titanium as, for example, shown in FIG. 5.

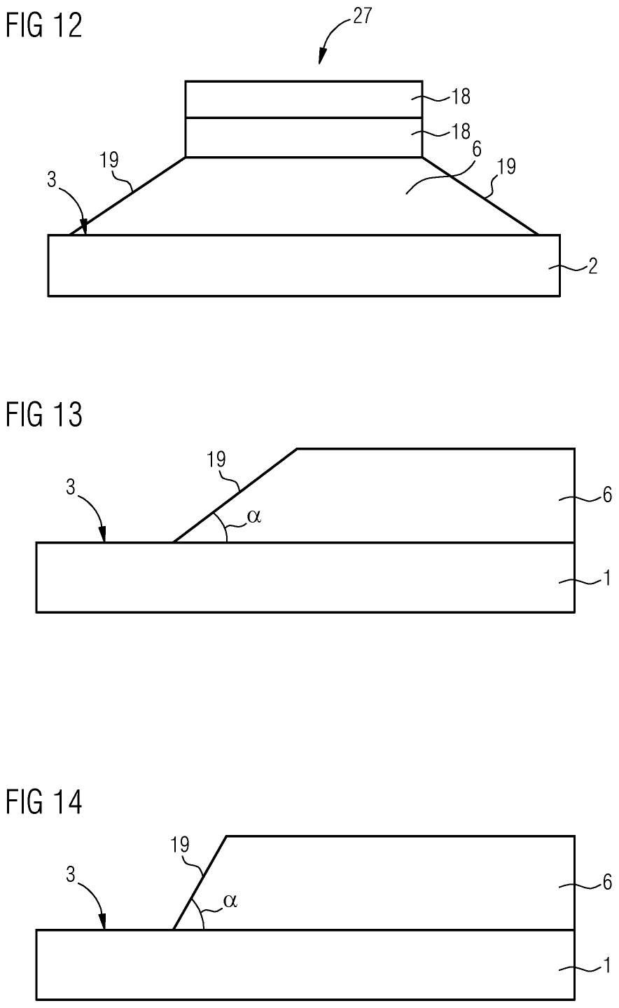

The semiconductor chip 27 according to the exemplary embodiment of FIG. 12 has a buffer layer 6 with inclined side faces 19. In particular, seen from the back side face 3 of the epitaxial semiconductor layer sequence to the solder layer 9, a cross-sectional area of the buffer layer 6 decreases, at present continuously. Particularly, the buffer layer 6 does not have any kinks in the side face 9.

FIG. 13 schematically shows a buffer layer 6 being deposited via e-beam evaporation under an ion-flow 7 resulting in a buffer layer 6 having inclined side faces 19. The side face 19 of the buffer layer 6 encloses an acute angle α with the back side face 3 of the epitaxial semiconductor layer sequence 1. The ion-flow 7 during deposition of the buffer layer 6 of FIG. 14 was decreased compared to the ion-flow 7 during the deposition of the buffer layer 6 of FIG. 13. As can be seen from FIGS. 13 and 14 the acute angle α of the buffer layer 6 decreases with increasing ion-flow 7.

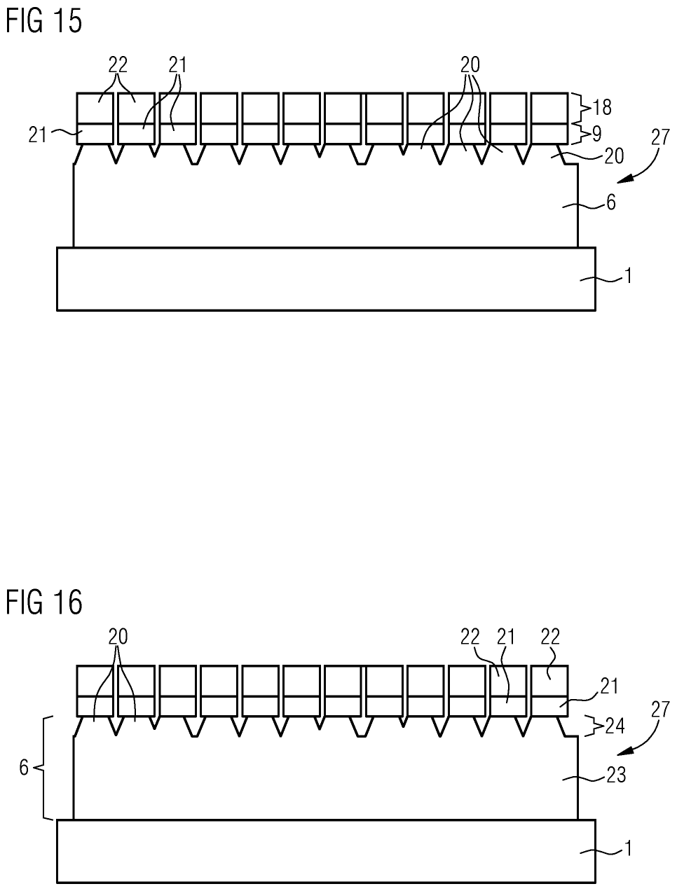

The semiconductor chip 27 according to the exemplary embodiment of FIG. 15 comprises a buffer layer 6 having a rough surface with peaks 20. Islands 21 of a solder layer 9 are deposited on the peaks 20. The islands 21 of the solder layer 9 are in direct contact with the peaks 20 of the buffer layer 6. The solder layer 9 is formed of the islands 21, wherein the islands 21 are not connected to each other. In other words, the solder layer 9 is formed of non-continuously connected islands 21 of a solder material. Islands 22 of a cap layer 18 are arranged on top of the islands 21 forming the solder layer 9. In other words, the cap layer 18 is, as is the solder layer 9, formed of islands 22 of a cap material, for example gold.

The semiconductor chip 27 according to FIG. 16 comprises, in contrast to the semiconductor chip 27 of FIG. 15, a buffer layer 6 with a flat sublayer 23 covered with a rough sublayer 24 having peaks 20. As already described in connection with FIG. 15, islands 21 of a solder layer 9 and islands 22 a cap 18 layer are arranged on the peaks 20 of the rough sublayer 24 forming a rough surface of the buffer layer 6.

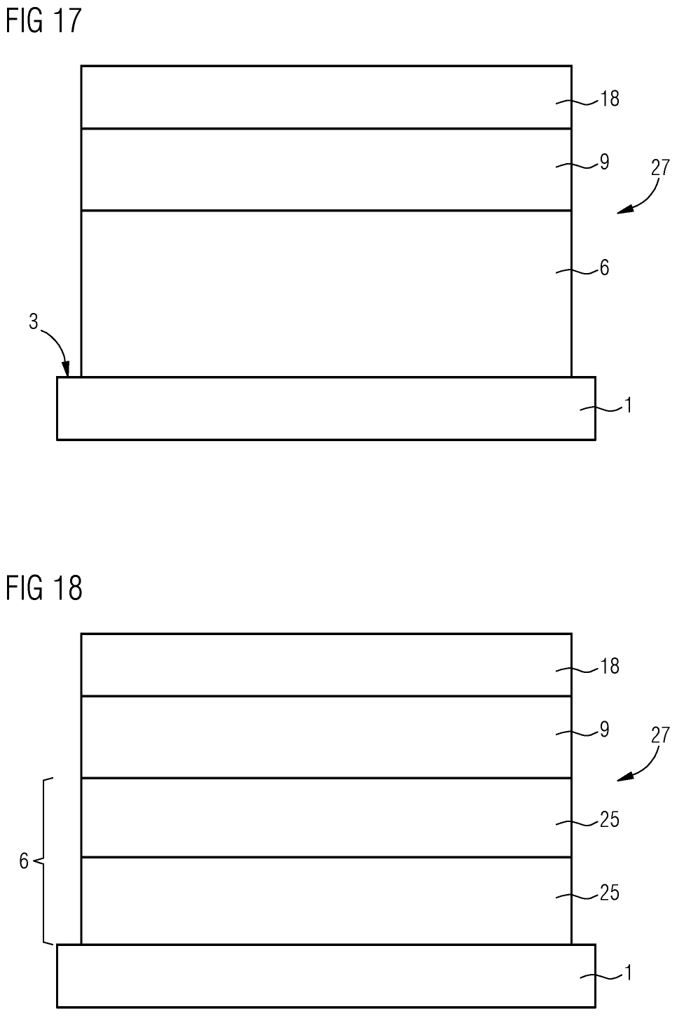

The semiconductor chip 27 according to the exemplary embodiment of FIG. 17 comprises a buffer layer 6 having a gradient in porosity. For example, seen from the back side face 3 of the epitaxial semiconductor layer sequence 1, the porosity of the buffer layer 6 decreases to a solder layer 9 or vice versa.

The semiconductor chip 27 according to the exemplary embodiment of FIG. 18 comprises a buffer layer 6 having two porous sublayers 25 with different porosity.

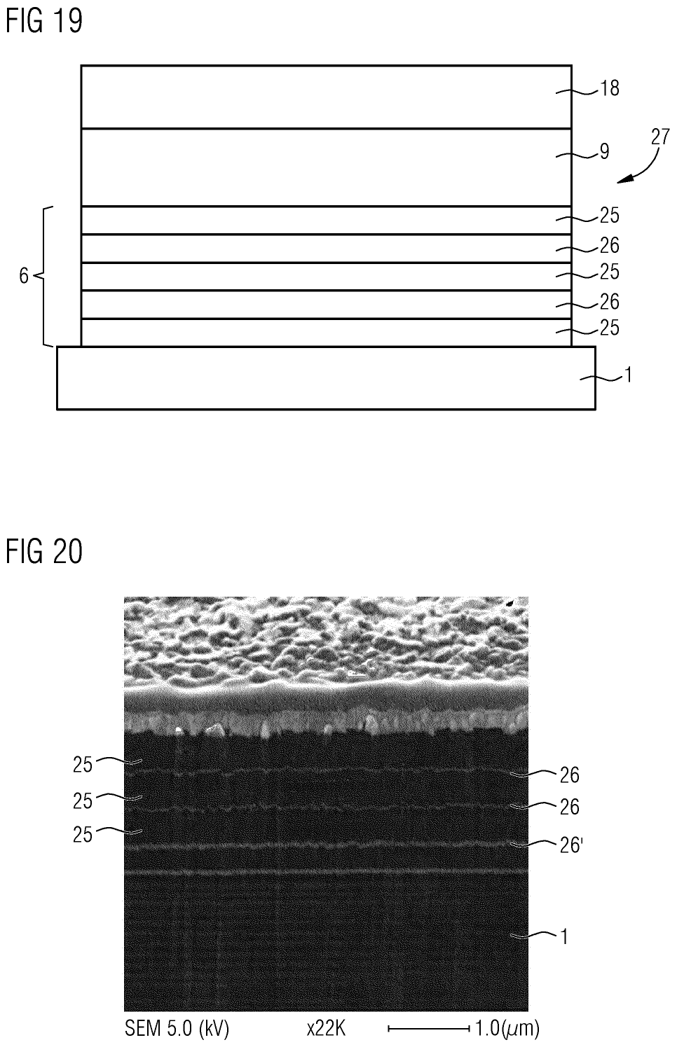

The semiconductor chip 27 according to the exemplary embodiment of FIG. 19 comprises a buffer layer 6 with different sublayers 25, 26. At present, the buffer layer 6 is formed of alternatingly arranged porous sublayers 25 and dense sublayers 26. The dense sublayers 26 and the porous buffer sublayers 25 comprise or consist of different materials.

FIG. 20 exemplarily shows a raster electron microscope image with a buffer layer 6 comprising porous titanium sublayers 25, two dense platinum layers 26 and one dense rhodium layer 26′.

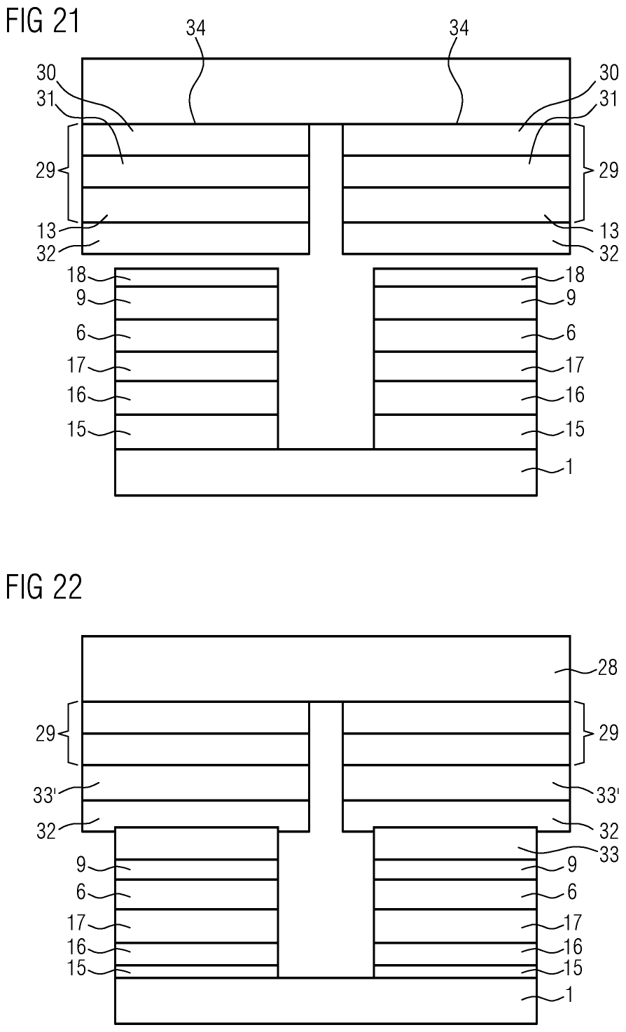

FIG. 21 shows a semiconductor chip 27 and a connection carrier 28 before the connection of the semiconductor chip 27 to the connection carrier 28 in order to form an arrangement. For example, the semiconductor chip 27 is embodied as already described in connection with FIG. 11.

At present the connection carrier 28 is a printed circuit board having connection points 29 on a mounting area 34. The connection points comprise a metal layer stack. The metal layer stack is at present formed by a copper layer 30, a nickel layer 31 and a gold layer 13 arranged in direct contact with each other in this order seen from the connection carrier 28. A solder paste 32 for soldering is arranged on each connection point 29 in direct contact.

The arrangement according to the exemplary embodiment of FIG. 22 shows the arrangement of FIG. 21 after soldering the semiconductor chip 27 to the connection points 29 of the connection carrier 28 by forming a solder joint 33 from the solder paste 33, the solder layer 9 and the cap layer 13 over the electrical contacts 15. A further solder joint 33′ is formed of the cap layer 13 of the connection points 29 and the solder paste 32.

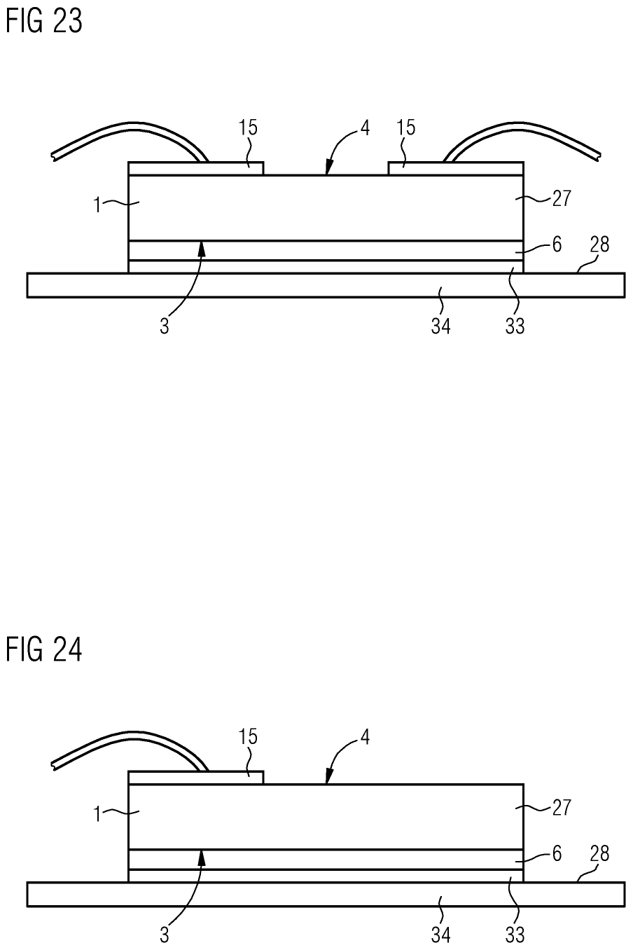

The arrangement according to the exemplary embodiment of FIG. 23 comprises a connection carrier 28 and a semiconductor chip 27. The connection carrier 28 comprises a mounting area 34 onto which the semiconductor chip 27 is applied.

The semiconductor chip 27 comprises an epitaxial semiconductor layer sequence 1 with a back side face 3 and a front side face 4 arranged opposite to the back side face 3. Over the front side face 3 of the epitaxial layer semiconductor sequence 1 two electrical contacts 15 are arranged, the electrical contacts 15 being configured to provide electrical current and/or voltage to the epitaxial semiconductor layer sequence 1 during operation.

A buffer layer 6 is arranged over the back side face 3 of the epitaxial semiconductor layer sequence 1. The buffer layer 6 completely covers the back side face 3 of the epitaxial layer sequence 1. A solder joint 33 is arranged over the buffer layer 6 and completely covers the buffer layer 6. The solder joint 33 mechanically stably connects the semiconductor chip 27 to the mounting area 34 of the connection carrier 28. It is not necessary that the solder joint 33 also provides an electrically conductive connection between the semiconductor chip 27 and the connection carrier 28, since the electrical contacts 15 of the semiconductor chip 27 are arranged over the front side face 4 of the epitaxial semiconductor layer sequence 1.

The arrangement according to the exemplary embodiment of FIG. 24 comprises, in contrast to the arrangement of FIG. 23, a semiconductor chip 27 having only one electrical contact 15 over a front side face 4 of the epitaxial semiconductor layer sequence 1. Therefore, the solder joint 33 also has to provide electrical contact between the semiconductor chip 27 and the connection carrier 28 besides a mechanically stable connection.

The present disclosure is not limited to the description of the embodiments. Rather, the present disclosure comprises each new feature as well as each combination of features, particularly each combination of features of the claims, even if the feature or the combination of features itself is not explicitly given in the claims or embodiments.

### REFERENCES

1 epitaxial semiconductor layer sequence
2 active layer
3 back side face
4 front side face
5 buffer layer
6 titanium layer
7 argon flow
8 etchant
9 solder layer
10 rhodium layer
11 titanium layer
12 platinum layer
13 gold layer
14 pore
15 electrical contact
16 adhesion layer
17 reflection layer
18 cap layer
19 side faces
20 peak
21 island of a solder layer
22 island of a cap layer
23 flat sublayer
24 rough sublayer
25 porous sublayers
26, 26′ dense sublayers
27 semiconductor chip
28 connection carrier
29 connection point
30 copper layer
31 nickel layer
32 solder paste
33, 33′ solder joint
34 mounting area 34
α acute angle

1. A semiconductor chip comprising:
an epitaxial semiconductor layer sequence,
a solder layer arranged over a back side face of the epitaxial semiconductor layer sequence,
a buffer layer arranged between the back side face of the epitaxial semiconductor layer sequence and the solder layer,
wherein
the buffer layer comprises a porous and/or rough metal, and
the porous and/or rough metal is porous and/or rough titanium.

2. (canceled)

3. The semiconductor chip according to claim 1, wherein
at least one electrical contact is arranged over the back side face of the epitaxial semiconductor layer sequence, and
the buffer layer is arranged between the electrical contact and the solder layer.

4. The semiconductor chip according to claim 1, wherein a cross-sectional area of the buffer layer decreases in a direction from the back side face of the epitaxial semiconductor layer sequence to the solder layer.

5. The semiconductor chip according to claim 1, wherein a side face of the buffer layer encloses an acute angle with the back side face of the epitaxial semiconductor layer sequence.

6. The semiconductor chip according to claim 1, wherein
the buffer layer has a rough surface having peaks, and
the solder layer is formed of islands on or over the peaks.

7. The semiconductor chip according to claim 1, wherein
the buffer layer has a rough surface having peaks, and
a cap layer formed of islands is arranged over the peaks.

8. The semiconductor chip according to claim 1, wherein the buffer layer has a porosity with a gradient.

9. The semiconductor chip according to claim 1, wherein the buffer layer has at least two sublayers comprising the same porous metal and having different porosity.

10. The semiconductor chip according to claim 1, wherein
the buffer layer comprises a plurality of porous sublayers and a plurality of dense sublayers,
the porous sublayers and the dense sublayers having different materials, and
the porous sublayers and the dense sublayers being arranged alternatingly.

11. The semiconductor chip according to claim 1, wherein a cap layer is arranged over the solder layer.

12. The semiconductor chip according to claim 1, wherein at least one of the following layers are arranged between the buffer layer and the back side face of the epitaxial semiconductor layer sequence: an adhesion layer, a reflection layer.

13. A method for producing a semiconductor chip comprising:
providing an epitaxial semiconductor layer sequence with a back side face,
arranging a buffer layer over the back side face, and
arranging a solder layer over the buffer layer, wherein
the buffer layer comprises a porous and/or rough metal, and
the porous and/or rough metal is porous and/or rough titanium.

14. The method according to claim 13, wherein arranging the buffer layer comprises depositing a metal by e-beam evaporation under an ion-flow.

15. The method according to claim 13, wherein arranging the buffer layer comprises depositing a metal by e-beam evaporation under an oblique angle or by sputtering under an oblique angle.

16. The method according to claim 13, wherein arranging the buffer layer comprises wet chemical etching.

17. An arrangement comprising:
a semiconductor chip,
a connection carrier with a mounting area, wherein
the semiconductor chip is mechanically stable connected to the mounting area of the connection carrier by a solder joint,
a buffer layer is arranged between the solder joint and the mounting area,
the buffer layer comprises a porous and/or rough metal, and
the porous and/or rough metal is porous and/or rough titanium.

18. The arrangement according to claim 17, wherein the semiconductor chip is also electrically conductive connected to the mounting area of the connection carrier by the solder joint.

19. The arrangement according to claim 17, wherein the semiconductor chip is a flip-chip.

20. The arrangement according to claim 17, wherein the semiconductor chip is a thin-film chip.
